(19) United States
(12) Patent Application Publication
(10) Pub. No.: US 2017/0110395 A1
(43) Pub. Date: Apr. 20, 2017

(54) SEMICONDUCTOR DEVICE

(71) Applicant: DENSO CORPORATION, Kariya-city, Aichi-pref. (JP)

(72) Inventors: Akira IWABUCHI, Kariya-city (JP); Atsushi KANAMORI, Kariya-city (JP); Kenji ONODA, Kariya-city (JP); Syoichirou OOMAE, Kariya-city (JP)

(73) Assignee: DENSO CORPORATION, Aichi (JP)

(21) Appl. No.: 15/128,648

(22) PCT Filed: Mar. 5, 2015
(86) PCT No.: PCT/JP2015/001209

§ 371 Date: Sep. 23, 2016

(30) Foreign Application Priority Data
Mar. 26, 2014 (JP) 2014-064195

(51) Int. Cl. H01L 23/50; H02M 7/00; H01L 23/31; H02M 7/537; H01L 23/495; H01L 25/07

(52) U.S. Cl. CPC H01L 23/50; H01L 23/49537; H01L 23/49562; H01L 23/49568; H01L 23/49575; H01L 25/07; H01L 23/3121; H02M 7/537; H02M 7/003; H02P 27/06

(57) ABSTRACT

A semiconductor device, in which a plurality of control terminals that correspond to a main terminal and the same semiconductor chip protrude from a surface of an encapsulating part, and a plurality of signal paths that include the plurality of control terminals are positioned so as to be aligned with the main terminal in a first direction. Provided in each of the plurality of signal paths are pairs of relay members having identical functions, and a first relay grouping that includes one relay member of the pair of relay and a second relay grouping that includes the other relay member of the pair are positioned neighboring each other aligned in the first direction, with the ordering of the first relay grouping being mirror-inverted relative to the second relay grouping.

### CROSS REFERENCE TO RELATED APPLICATION

This application is based on Japanese Patent Application No. 2014-64195 filed on Mar. 26, 2014, the disclosure of which is incorporated herein by reference.

### TECHNICAL FIELD

The present disclosure relates to a semiconductor device.

### BACKGROUND ART

There has been known a semiconductor device disclosed in Patent Literature 1 as a device in which a main terminal and a plurality of control terminals corresponding to the same semiconductor chip protrude from one face of an encapsulating portion, signal paths including the control terminals are arranged side by side in a first direction, and the main terminal is arranged alongside the signal paths in the first direction.

The semiconductor device disclosed in Patent Literature 1 includes six semiconductor elements (semiconductor chips) making up a three-phase inverter. A wiring member (the main terminal) is connected to each of a collector electrode and an emitter electrode of the semiconductor chip. On the other hand, a wiring member (the control terminal) is connected to a gate electrode via a bonding wire (a relay member). These main terminal and control terminals protrude from a resin molded portion (the encapsulating portion).

Moreover, for example, the main terminal for output of each phase and the control terminal of each phase protrude from the same face of the encapsulating portion, where the control terminal and the main terminal are arranged side by side for each phase in the first direction along which the control terminals are arranged.

The control terminal is electrically connected to a control electrode via the relay member as described above, so that the signal path is formed of the relay member and the control terminal. That is, multiple signal paths and main terminals are arranged side by side in the first direction.

In the event of a short circuit causing a large current to flow instantaneously between the main terminal arranged alongside the control terminal and another main terminal in such configuration, magnetic coupling between the main terminal and the signal path arranged side by side generates noise, which propagates through the signal path to possibly cause a malfunction.

### PRIOR ART LITERATURES

### Patent Literature

Patent Literature 1: JP 2012-146919 A

### SUMMARY OF INVENTION

It is an object of the present disclosure to provide a semiconductor device capable of preventing the malfunction resulting from the noise generated in the event of the short circuit.

A semiconductor device according to an aspect of the present disclosure includes at least one semiconductor chip, an encapsulating portion, a plurality of main terminals, a plurality of relay members and a plurality of control terminals. The semiconductor chip on which a switching device is arranged includes a pair of main electrodes and a plurality of control electrodes; the encapsulating portion encapsulates the at least one semiconductor chip; the plurality of main terminals are electrically connected to the main electrodes and protrude from the encapsulating portion; the plurality of relay members are respectively connected to the plurality of control electrodes; and the plurality of control terminals are respectively electrically connected to the plurality of control electrodes through the plurality of relay members, generate a plurality of signal paths together with the respective relay members, and protrude from the encapsulating portion. The plurality of main terminals include first main terminals protruding from one face of the encapsulating portion, and second main terminals protruding from a face different from the one face; the plurality of control terminals corresponding to a same semiconductor chip protrude from the one face, the plurality of signal paths including the control terminals are arranged side by side in a first direction, and the first main terminals are arranged alongside the plurality of signal paths in the first direction.

The relay members having a same function are provided in a pair at each of the plurality of signal paths arranged side by side with the first main terminals; and a first relay group including one of the pair of the relay members and a second relay group including another one of the pair are arranged next to each other along the first direction while an order of arrangement of the first relay group and the second relay group exhibits a mirror-inverted relationship.

The malfunction resulting from the noise is not dependent on the absolute magnitude of the noise itself generated in each signal path but occurs when there is a large difference in noise voltages between the signal paths arranged side by side. According to the semiconductor device, each signal path has a nearly equal mutual inductance that is obtained by combining a mutual inductance between one of the pair of relay members and the first main terminal and a mutual inductance between another one of the pair of relay members and the first main terminal. The malfunction resulting from the noise can thus be prevented even when a large current flows instantaneously between the first main terminal and the second main terminal in the event of a short circuit.

A semiconductor device according to another aspect of the present disclosure includes at least one semiconductor chip, an encapsulating portion, a plurality of relay members, and a plurality of control terminals. The semiconductor chip on which a switching device is arranged includes a pair of main electrodes and a plurality of control electrodes; the encapsulating portion encapsulates the semiconductor chip; the plurality of main terminals are electrically connected to the main electrodes and protrude from the encapsulating portion; the plurality of relay members are respectively connected to the plurality of control electrodes; and the plurality of control terminals are electrically connected to the plurality of control electrodes through the plurality of relay members, form a plurality of signal paths together with the respective relay members, and protrude from the encapsulating portion. The plurality of main terminals include first main terminals protruding from one face of the encapsulating portion, and second main terminals protruding from a face different from the one face; the plurality of control terminals corresponding to a same semiconductor chip protrude from the one face, the signal paths including the control terminals are arranged side by side in a first direction, and the first main terminals are arranged alongside the signal paths in the first direction; the first main terminals having a same function are provided in a pair; and the pair of the first main terminals are arranged at both sides of a plurality of the signal paths while interposing the plurality of the signal paths between the first main terminals in the first direction.

As described above, the malfunction resulting from the noise is not dependent on the absolute magnitude of the noise itself generated in each signal path but occurs when there is a large difference in the noise voltages between the signal paths arranged side by side. According to the semiconductor device, each signal path has a nearly equal mutual inductance that is obtained by combining a mutual inductance between one of the pair of first main terminals and the signal path and a mutual inductance between another one of the pair of first main terminals and the signal path. The malfunction resulting from the noise can thus be prevented even when a large current flows instantaneously between the first main terminal and the second main terminal in the event of a short circuit.

### BRIEF DESCRIPTION OF DRAWINGS

The above and other objects, features and advantages of the present disclosure will become more apparent from the following detailed description made with reference to the accompanying drawings. In the drawings:

FIG. 1 is a circuit diagram of a semiconductor device according to a first embodiment;

FIG. 2 is a perspective view illustrating a schematic configuration of the semiconductor device illustrated in FIG. 1;

FIG. 3 is a diagram from which an encapsulating portion and an insulating sheet illustrated in FIG. 2 are omitted;

FIG. 4 is a diagram from which some of heat sinks illustrated in FIG. 3 are omitted;

FIG. 5 is an enlarged view of a region V indicated with a broken line in FIG. 4;

FIG. 6 is an enlarged view of an area around a bonding wire illustrated in FIG. 5;

FIG. 7 is an equivalent circuit diagram provided to illustrate an effect of malfunction prevention and corresponding to FIG. 5;

FIG. 8 is an enlarged view of an area around a bonding wire according to a first variation;

FIG. 9 is a perspective view illustrating a schematic configuration of a semiconductor device according to a second variation;

FIG. 10 is a plan view illustrating a semiconductor device according to a third variation;

FIG. 11 is a plan view illustrating a semiconductor device according to a fourth variation;

FIG. 12 is a plan view illustrating a semiconductor device according to a fifth variation;

FIG. 13 is a plan view illustrating a semiconductor device according to a sixth variation;

FIG. 14 is a plan view illustrating a semiconductor device according to a seventh variation;

FIG. 15 is a plan view illustrating a schematic configuration of a semiconductor device according to a second embodiment;

FIG. 16 is a diagram from which an encapsulating portion, an insulating sheet and some of heat sinks illustrated in FIG. 15 are omitted;

FIG. 17 is an enlarged view of a region XVII indicated with a broken line in FIG. 16;

FIG. 18 is an equivalent circuit diagram provided to illustrate an effect of malfunction prevention and corresponding to FIG. 17;

FIG. 19 is a plan view illustrating a semiconductor device according to an eighth variation; and

FIG. 20 is a plan view illustrating a semiconductor device according to a ninth variation.

### EMBODIMENTS FOR CARRYING OUT INVENTION

Embodiments of the present disclosure will now be described with reference to the drawings. Note that the same reference numeral is assigned to parts that are identical or equivalent to one another in the following drawings. Moreover, a Z-direction indicates a direction of the thickness of a semiconductor chip. A Y-direction indicates a direction which is orthogonal to the Z-direction and in which a control terminal extends. An X-direction indicates a direction orthogonal to both the Y-direction and the Z-direction. Moreover, a planar shape refers to a shape along a surface defined by the X-direction and the Y-direction, unless otherwise specified.

### First Embodiment

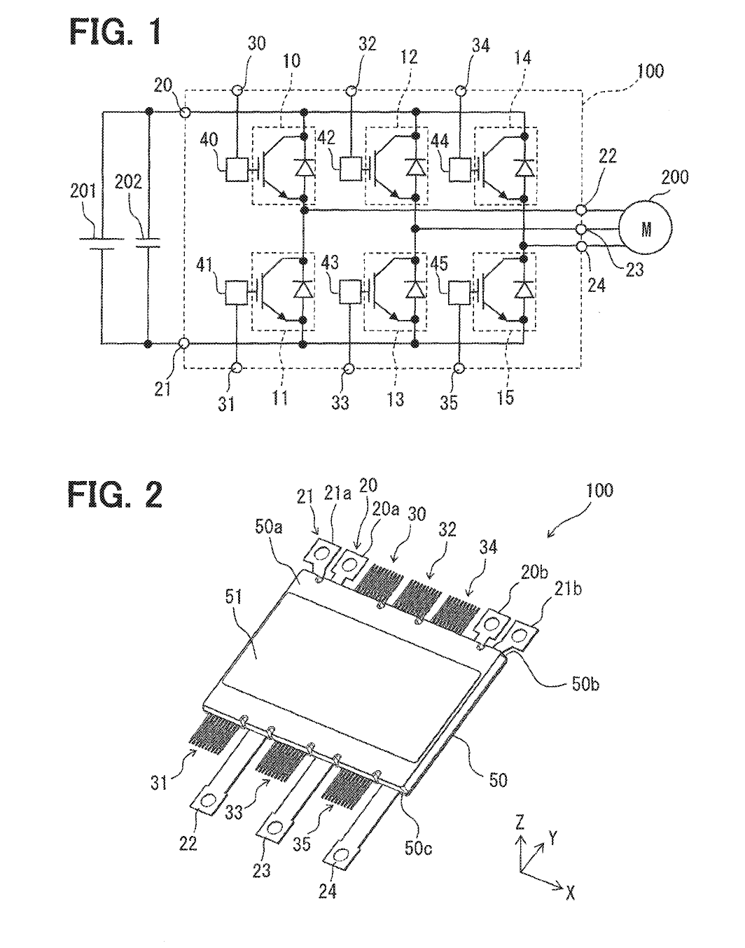

First, the configuration of a semiconductor device 100 according to the present embodiment will be described with reference to FIGS. 1 to 6.

As illustrated in FIG. 1, the semiconductor device 100 includes three phases of upper/lower arms that are connected between a positive electrode (high potential side) and a negative electrode (low potential side) of a DC power supply 201, in order to drive a motor 200 as a load. The semiconductor device 100 is thus constructed as a three-phase inverter and converts DC power into three-phase AC to be output to the motor 200. The semiconductor device 100 is mounted in an electric vehicle and a hybrid vehicle, for example. A smoothing capacitor 202 is illustrated in FIG. 1 as well.

A semiconductor chip making up each arm includes a power switching device such as an IGBT or a MOSFET and an FWD device connected in anti-parallel with the switching device. Note that the power switching device and the FWD device can also be constructed in separate chips. In the present: embodiment, the semiconductor device 100 includes six semiconductor chips 10 to 15 each adopting an n-channel IGBT device as the switching device. The semiconductor chip 10 on an upper arm side and the semiconductor chip 11 on a lower arm side make up upper/lower arms for a U-phase. Likewise, the semiconductor chip 12 on the upper arm side and the semiconductor chip 13 on the lower arm side make up upper/lower arms for a V-phase. The semiconductor chip 14 on the upper arm side and the semiconductor chip 15 on the lower arm side make up upper/lower arms for a W-phase.

The semiconductor device 100 further includes a P-terminal 20, an N-terminal 21, output terminals 22 to 24, and control terminals 30 to 35 as terminals provided for external connection. Among those terminals, the P-terminal 20, the N-terminal 21, and the output terminals 22 to 24 are equivalent to main terminals. Note that the main terminal is also called a power terminal and the control terminal is also called a signal terminal.

The P-terminal 20 is a terminal connected on the positive electrode side of the DC power supply 201, while the N-terminal 21 is a terminal connected on the negative electrode side of the DC power source. The P-terminal 20 is electrically connected to a collector electrode of the IGBT device formed on each of the semiconductor chips 10, 12 and 14 on the upper arm side. The N-terminal 21 is electrically connected to an emitter electrode of the IGBT device formed on each of the semiconductor chips 11, 13 and 15 on the lower arm side.

Among the output terminals 22 to 24 connected to three phase lines of the motor 200, the output terminal 22 for the U-phase is electrically connected to an emitter electrode of the IGBT device formed on the semiconductor chip 10 and a collector electrode of the IGBT device formed on the semiconductor chip 11. Likewise, the output terminal 23 for the V-phase is electrically connected to an emitter electrode of the IGBT device formed on the semiconductor chip 12 and a collector electrode of the IGBT device formed on the semiconductor chip 13. The output terminal 24 for the W-phase is electrically connected to an emitter electrode of the IGBT device formed on the semiconductor chip 14 and a collector electrode of the IGBT device formed on the semiconductor chip 15. Note that the collector electrode and the emitter electrode of each of the semiconductor chips 10 to 15 are equivalent to main electrodes.

Each of the control terminals 30 to 35 is a terminal through which various signals that control drive of the device formed on each of the semiconductor chips 10 to 15 are input or output, and is electrically connected to a control electrode (pad) of each of the semiconductor chips 10 to 15. The control terminal 30 corresponds to the semiconductor chip 10, and the control terminal 31 corresponds to the semiconductor chip 11. Likewise, the control terminal 32 corresponds to the semiconductor chip 12, and the control terminal 33 corresponds to the semiconductor chip 13. The control terminal 34 corresponds to the semiconductor chip 14, and the control terminal 35 corresponds to the semiconductor chip 15.

In the present embodiment, each of the control terminals 30 to 35 includes a total of five terminals used for a gate drive signal, a Kelvin emitter (detecting a potential of the emitter electrode), an anode potential of a temperature-sensitive diode formed on each of the semiconductor chips 10 to 15, a cathode potential of the temperature-sensitive diode formed thereon, and a current sense. Each of the control terminals further includes a total of five terminals used for a power source (two terminals), an error check, test mode setting, and a gate potential check.

The semiconductor device 100 also includes, on the semiconductor chips 10 to 15, driver ICs 40 to 45 each formed of a drive circuit that controls drive of the device formed on the corresponding semiconductor chip. Each of the driver ICs 40 to 45 generates an analog signal such as a gate drive signal on the basis of a control signal (digital signal) input from a microcomputer not shown. The driver IC also converts a value (analog value) detected by the temperature-sensitive diode into a digital signal and outputs the signal. Note that each of the driver ICs 40 to 45 is equivalent to a driver chip.

As illustrated in FIG. 2, the semiconductor device 100 includes an encapsulating portion 50 that integrally encapsulates the semiconductor chips 10 to 15. The semiconductor device is thus a 6-in-1 package formed by encapsulating the six semiconductor chips 10 to 15 making up the three-phase inverter in the encapsulating portion 50.

The encapsulating portion 50 is formed by using resin material, for example. In the present embodiment, the encapsulating portion is formed by a transfer mold method using epoxy resin. The encapsulating portion 50 has a substantially rectangular planar shape, where one face 50a in the Z-direction and a face (not shown) on the reverse side of the one face 50a are roughly flat. A heat-dissipating surface of each of heat sinks 60 to 67 to be described is exposed from those faces.

An insulating sheet 51 is stuck on each of the one face 50a and the face on the reverse side of the face 50a to cover each heat-dissipating surface. The insulating sheet 51 electrically separates the semiconductor device 100 from a cooler that is disposed on each of both sides of the semiconductor device 100 in the Z-direction to allow for heat dissipation from both sides of the semiconductor device 100.

The P-terminals 20 (20a and 20b), the N-terminals 21 (21a and 21b), and the control terminals 30, 32, and 34 corresponding to the semiconductor chips 10, 12, and 14 on the upper arm side protrude from a side face 50b, among side faces connecting the one face 50a and the face on the reverse side of the face 50a. A part of each of the terminals 20, 21, 30, 32, and 34 extending in the Y-direction protrudes from the side face 50b. The ten terminals making up each of the control terminals 30, 32, and 34 are arranged side by side in the X-direction, and the control terminals 30, 32, and 34 are arranged side by side with one another in the X-direction near the center of the side face 50b. These control terminals 30, 32, and 34 are then interposed between the P-terminal 20a and the N-terminal 21a arranged on one side of the X-direction, and the P-terminal 20b and the N-terminal 21b arranged on another side of the X-direction. That is, the N-terminal 21a, the P-terminal 20a, the control terminal 30, the control terminal 32, the control terminal 34, the P-terminal 20b, and the N-terminal 21b are arranged in this order from one end side of the X-direction.

On the other hand, the output terminals 22 to 24 and the control terminals 31, 33, and 35 corresponding to the semiconductor chips 11, 13, and 15 on the lower arm side protrude from a side face 50c opposite to the side face 50b. A part of each of the terminals 22 to 24, 31, 33, and 35 extending in the Y-direction protrudes from the side face 50c. The ten terminals making up each of the control terminals 31, 33, and 35 are arranged side by side in the X-direction. The control terminal 31, the output terminal 22, the control terminal 33, the output terminal 23, the control terminal 35 and the output terminal 24 are arranged in this order from one end side of the X-direction. When the output terminals 22 to 24 correspond to first main terminals, for example, the P-terminal 20 and the N-terminal 21 are equivalent to second main terminals while the side face 50c is equivalent to one face of the encapsulating portion. On the contrary, when the P-terminal 20 or the N-terminal 21 corresponds the first main terminal, the output terminals 22 to 24 are equivalent to the second main terminals while the side face 50b is equivalent to the one face of the encapsulating portion. The X-direction is equivalent to a first direction.

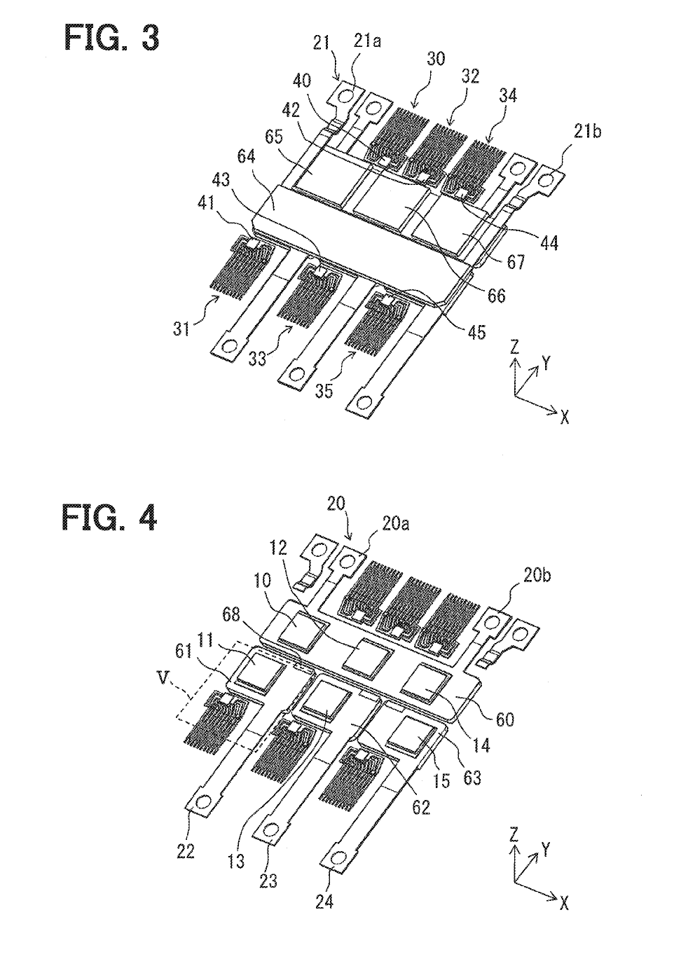

The semiconductor device 100 includes the heat sinks 60 to 67 as illustrated in FIGS. 3 and 4. The heat sinks 60 to 67 serve as an electrical relay function with the corresponding P-terminal 20, N-terminal 21, output terminals 22 to 24 and semiconductor chips 10 to 15, and serve a function of dissipating heat generated by the semiconductor chips 10 to 15.

The heat sink 60 is formed integrally with the P-terminals 20 (20a and 20b). The semiconductor chips 10, 12, and 14 on the upper arm side are arranged on one face of the heat sink 60 while causing faces on which the collector electrodes are formed to face the one face, so that each collector electrode is electrically connected to the heat sink 60. The heat sink 60 has a rectangular planar shape with the X-direction corresponding to a longitudinal direction of the rectangle, and the semiconductor chips 10, 12, and 14 are arranged side by side in the X-direction.

On the other hand, the semiconductor chips 11, 13, and 15 on the lower arm side are arranged on the heat sinks 61 to 63, respectively. The heat sink 61 is formed integrally with the output terminal 22 for the U-phase. The semiconductor chip 11 is arranged on one face of the heat sink 61 while causing a face on which the collector electrode is formed to face the one face, so that the collector electrode is electrically connected to the heat sink 61. The heat sink 62 is formed integrally with the output terminal 23 for the V-phase. The semiconductor chip 13 is arranged on one face of the heat sink 62 while causing a face on which the collector electrode is formed to face the one face, so that the collector electrode is electrically connected to the heat sink 62. The heat sink 63 is formed integrally with the output terminal 24 for the W-phase. The semiconductor chip 15 is arranged on one face of the heat sink 63 while causing a face on which the collector electrode is formed to face the one face, so that the collector electrode is electrically connected to the heat sink 63. Note that chip-mounting faces of the heat sinks 60 to 63 are on the same side in the Z-direction. The thickness of each of the heat sinks 60 to 63 is substantially the same, and a face on the reverse side of the chip-mounting face of each of the heat sinks 60 to 63 corresponds to a heat-dissipating surface that is exposed from the face on the reverse side of the one face 50a of the encapsulating portion 50.

The heat sink 64 is disposed on a face of each of the semiconductor chips 11, 13, and 15, the face corresponding to the reverse side of the face that faces the corresponding heat sink 61, 62, or 63. The heat sink 64 is electrically connected to the N-terminals 21 (21a and 21b). The heat sink 64 has a rectangular planar shape with the X-direction corresponding to a longitudinal direction of the rectangle, and is disposed across the semiconductor chips 11, 13, and 15. The heat sink 64 is electrically connected to the emitter electrodes of the semiconductor chips 11, 13, and 15.

On the other hand, the heat sinks 65 to 67 are disposed on faces of the semiconductor chips 10, 12, and 14 on the upper arm side, respectively, the faces corresponding to the reverse side of the faces that face the heat sink 60. The heat sink 65 is electrically connected to the emitter electrode of the semiconductor chip 10. The heat sink 66 is electrically connected to the emitter electrode of the semiconductor chip 12. The heat sink 67 is electrically connected to the emitter electrode of the semiconductor chip 14. Each of the heat sinks 65 to 67 is electrically connected to the heat sink 61, 62, or 63 of the corresponding phase. In the present embodiment, a protrusion not shown is provided to each of the heat sinks 65 to 67 and connected to a link portion 68 of each of the heat sinks 61 to 63.

Note that the thickness of each of the heat sinks 64 to 67 is substantially the same, and a face on the reverse side of the face that faces the corresponding semiconductor chip 10 to 15 of each of the heat sinks 64 to 67 serves as a heat-dissipating surface that is exposed from the one face 50a of the encapsulating portion 50. Moreover, as described above, each of the semiconductor chips 10 to 15 has a double-sided electrode structure including the collector electrode on one face and the emitter electrode on a reverse face of the one face.

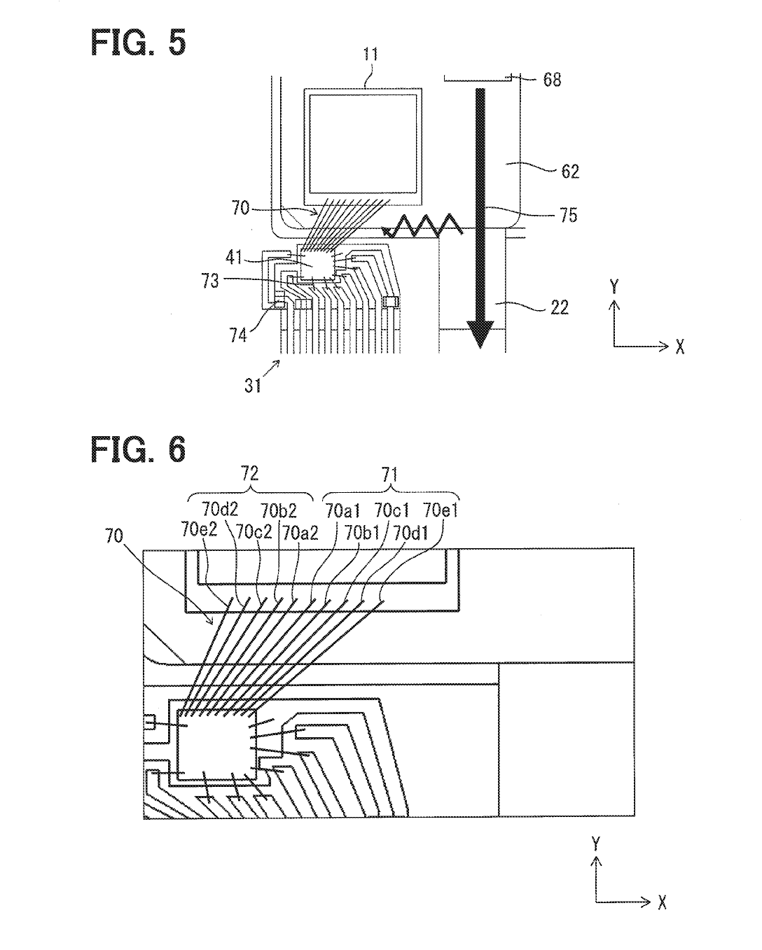

FIGS. 5 and 6 illustrate the lower arm side of the U-phase. While the lower arm of the U-phase will be described, another arm has a configuration similar to that described below. The semiconductor chip 11 is electrically connected to the corresponding driver IC 41 via a bonding wire 70. The bonding wire 70 is equivalent to a relay member.

Together with the control terminal 31 described above, the bonding wire 70 forms a signal path provided to control drive of the device formed on the semiconductor chip 11. A plurality of signal paths connected to the semiconductor chip 11 is arranged side by side in the X-direction, and the output terminal 22 for the U-phase being the main terminal is arranged alongside the plurality of signal paths.

In the present embodiment, the bonding wire 70 includes a first wire group 71 and a second wire group 72. The first wire group 71 is equivalent to a first relay group, while the second wire group 72 is equivalent to a second relay group.

The first wire group 71 includes five bonding wires 70a1 to 70e1. The bonding wire 70a1 is provided for the cathode potential of the temperature-sensitive diode formed on the semiconductor chip 11, whereas the bonding wire 70b1 is provided for the anode potential of the diode. The bonding wire 70c1 is provided for the gate drive signal of the IGBT device, and the bonding wire 70d1 is provided for the current sense. The bonding wire 70e1 is provided for the Kelvin emitter having a reference potential (ground) for each signal path.

The second wire group 72 includes five bonding wires 70a2 to 70e2. The bonding wire 70a2 is provided for the cathode potential of the temperature-sensitive diode formed on the semiconductor chip 11, whereas the bonding wire 70b2 is provided for the anode potential of the diode. The bonding wire 70c2 is provided for the gate drive signal of the IGBT device, and the bonding wire 70d2 is provided for the current sense. The bonding wire 70e2 is provided for the Kelvin emitter potential corresponding to the reference potential (ground) for each signal path.

The number of the bonding wires 70 and the functions thereof are the same between the first wire group 71 and the second wire group 72. The bonding wires 70a1 and 70a2 are the bonding wires 70 having the same function, for example. That is, there are provided five signal paths provided for the cathode potential of the temperature-sensitive diode formed on the semiconductor chip 11, the anode potential of the diode, the gate drive signal of the IGBT device, the current sense, and the Kelvin emitter. The signal path provided for the cathode potential is referred to as a first signal path. The signal path provided for the anode potential is referred to as a second signal path. The signal path provided for the gate drive signal is referred to as a third signal path. The signal path provided for the current sense is referred to as a fourth signal path. The signal path provided for the Kelvin emitter is referred to a fifth signal path. Moreover, the bonding wire 70 is branched off to have two parts in each signal path. Although not shown in the figure, two sets of electrodes (pads) of the semiconductor chip 11 and the driver IC 41 are provided in each signal path.

The bonding wires 70 having the same function in the first wire group 71 and the second wire group 72 are arranged at mirror-inverted positions along the X-direction, as illustrated in FIG. 6. The bonding wires 70a1 to 70e1 making up the first wire group 71 are arranged side by side in the X-direction. Specifically, the bonding wire 70a1, the bonding wire 70b1, the bonding wire 70c1, the bonding wire 70d1 and the bonding wire 70e1 are arranged in this order. The bonding wires 70a2 to 70e2 making up the second wire group 72 are also arranged side by side in the X-direction. The second wire group 72 is arranged next to the first wire group 71. The bonding wire 70a2 is arranged next to the bonding wire 70a1. The bonding wire 70a2, the bonding wire 70b2, the bonding wire 70c2, the bonding wire 70d2 and the bonding wire 70e2 are arranged in this order in a direction away from the bonding wire 70a1.

Note that, as illustrated in FIG. 5, the driver IC 41 is electrically connected to the control terminal 31 via a bonding wire 73. Moreover, a passive component 74 such as a chip resistor or a chip capacitor is implemented across some of the control terminals 31.

An effect of the semiconductor device 100 according to the present embodiment will now be described with reference to FIGS. 5 to 8. While the effect will be described by taking the lower arm side of the U-phase as an example, the description applies to the other arm as well.

The semiconductor device 100 includes the driver IC 41 in the present embodiment. Accordingly, among the signal paths described above, a digital signal is transmitted to the control terminal 31 while an analog signal is transmitted to the bonding wire 70. The bonding wire 70 to which the analog signal is transmitted has a sufficiently larger self-inductance than the control terminal 31. The self-inductance of the bonding wire 70 may thus be considered in considering a mutual inductance with respect to the output terminal 22 arranged alongside the bonding wire. Note that a malfunction is less likely to occur when noise is superimposed on the digital signal transmitted to the control terminal 31, but is more likely to occur when noise is superimposed on the analog signal transmitted to the bonding wire 70.

When a ground fault of the output terminal 22 causes a large current 75 to flow instantaneously from the P-terminal 20 toward the output terminal 22 via the link portion 68 as illustrated in FIG. 5, for example, a noise voltage formed by magnetic coupling is determined by a product of the mutual inductance of each signal path and a temporal change in a conduction current di/dt. The noise of 2 V is generated when di/dt equals 2 kA/ps and the mutual inductance equals 1 nH, for example.

When the large current 75 flows instantaneously as described above, the magnetic coupling causes noise in each signal path. However, the malfunction resulting from the noise is not dependent on the absolute magnitude of the noise itself generated in each signal path but occurs when there is a large difference in the noise voltages between the signal paths arranged side by side. Therefore, the malfunction does not occur when, with noise being generated in each signal path, there is virtually no difference in the noise voltages. Regarding the five signal paths described above, the one for the Kelvin emitter potential serves as the reference potential (ground) for each signal path, so that the remaining four signal paths operate with reference to the Kelvin emitter potential. Therefore, the malfunction does not occur when, with noise being superimposed, there is virtually no difference in potential with respect to the Kelvin emitter potential. The mutual inductance however increases as the distance between self-inductances generating the mutual inductance is closer and decreases as the distance is farther.

On the other hand, in the present embodiment, each of the five signal paths has the bonding wire 70 that is branched off into two parts as described above. That is, the bonding wires 70 having the same function are provided as a pair. The first wire group 71 including one of the pair of the bonding wires 70 and the second wire group 72 including another one of the pair are arranged next to each other in the X-direction, where the order of arrangement of the bonding wires exhibits a mirror-inverted relationship.

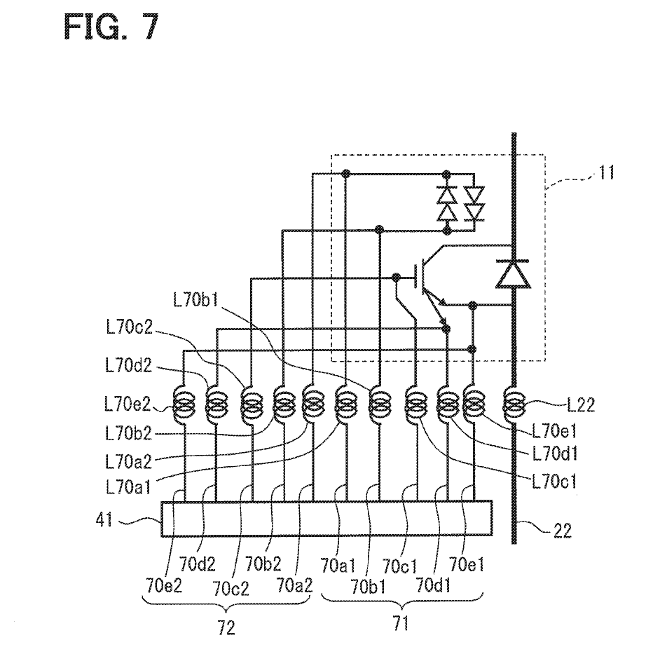

FIG. 7 illustrates an equivalent circuit diagram of the configuration illustrated in FIGS. 5 and 6. As described above, the first wire group 71 and the second wire group 72 are arranged in this order from the side of the output terminal 22 along the X-direction, specifically in the order of the bonding wire 70e1, the bonding wire 70d1, the bonding wire 70c1, the bonding wire 70b1, the bonding wire 70a1, the bonding wire 70a2, the bonding wire 70b2, the bonding wire 70c2, the bonding wire 70d2, and the bonding wire 70e2. FIG. 7 also illustrates a self-inductance L22 of the output terminal 22. Also illustrated are self-inductances L70a1, L70b1, L70c1, L70d1, and L70e1 of the bonding wire 70a1, the bonding wire 70b1, the bonding wire 70c1, the bonding wire 70d1 and the bonding wire 70e1, respectively, Moreover, self-inductances L70a2, L70b2, L70c2, L70d2, and L70e2 of the bonding wire 70a2, the bonding wire 70b2, the bonding wire 70c2, the bonding wire 70d2 and the bonding wire 70e2 are illustrated, respectively.

The bonding wire 70e1 is the closest to the output terminal 22 whereas the bonding wire 70e2 is the farthest from the output terminal 22, the bonding wires making up the fifth signal path provided for the Kelvin emitter corresponding to the reference potential of each signal path. The mutual inductance is thus large between the bonding wire 70e1 and the output terminal 22 and small between the bonding wire 70e2 and the output terminal 22. Therefore, a combined mutual inductance, namely the mutual inductance of the fifth signal path, takes nearly a median value of the mutual inductances.

Likewise, the bonding wire 70d1 is the second closest to the output terminal 22 while the bonding wire 70d2 is the second farthest from the output terminal 22, the bonding wires making up the fourth signal path. Therefore, the mutual inductance (combined mutual inductance) of the fourth signal path is nearly equal to the mutual inductance of the fifth signal path.

The bonding wire 70c1 is the third closest to the output terminal 22 while the bonding wire 70c2 is the third farthest from the output terminal 22, the bonding wires making up the third signal path. Therefore, the mutual inductance (combined mutual inductance) of the third signal path is also nearly equal to the mutual inductance of the fifth signal path.

The bonding wire 70b1 is the fourth closest to the output terminal 22 while the bonding wire 70b2 is the fourth farthest from the output terminal 22, the bonding wires making up the second signal path. Therefore, the mutual inductance (combined mutual inductance) of the second signal path is also nearly equal to the mutual inductance of the fifth signal path.

The bonding wire 70a1 is the fifth closest to the output terminal 22 while the bonding wire 70a2 is the fifth farthest from the output terminal 22, the bonding wires making up the first signal path. Therefore, the mutual inductance (combined mutual inductance) of the first signal path is also nearly equal to the mutual inductance of the fifth signal path.

The five signal paths have nearly equal combined inductances in the present embodiment, as described above. This allows each signal path to have a nearly equal noise voltage when the large current 75 flows instantaneously. As a result, with the noise being superimposed, there is almost no difference in potential of each signal path with reference to the Kelvin emitter potential. The malfunction of the semiconductor chip 11 or the driver IC 41 resulting from the noise can thus be prevented.

Moreover, in the present embodiment, the P-terminal 20, the N-terminal 21, and the control terminals 30, 32 and 34 protrude from the side face 50b of the encapsulating portion 50 and extend in the direction orthogonal to the Z-direction, whereas the output terminals 22 to 24 and the control terminals 31, 33 and 35 protrude from the opposite side face 50c and extend in the direction orthogonal to the Z-direction. The build in the Z-direction can be reduced in size as a result. Moreover, heat generated in the semiconductor device 100 can be dissipated through both faces of the device in the Z-direction. In particular, in the present embodiment, the heat-dissipating surfaces of the heat 2.5 sinks 60 to 67 are exposed so that heat dissipation can be enhanced while preventing the malfunction resulting from the noise.

(Variation)

In the present embodiment, there has been described the example where the bonding wires 70 having the same function are provided in pairs in all the six arms. The bonding wires 70 having the same function may however be provided in pairs only in some of the six arms such as only on the lower arm side.

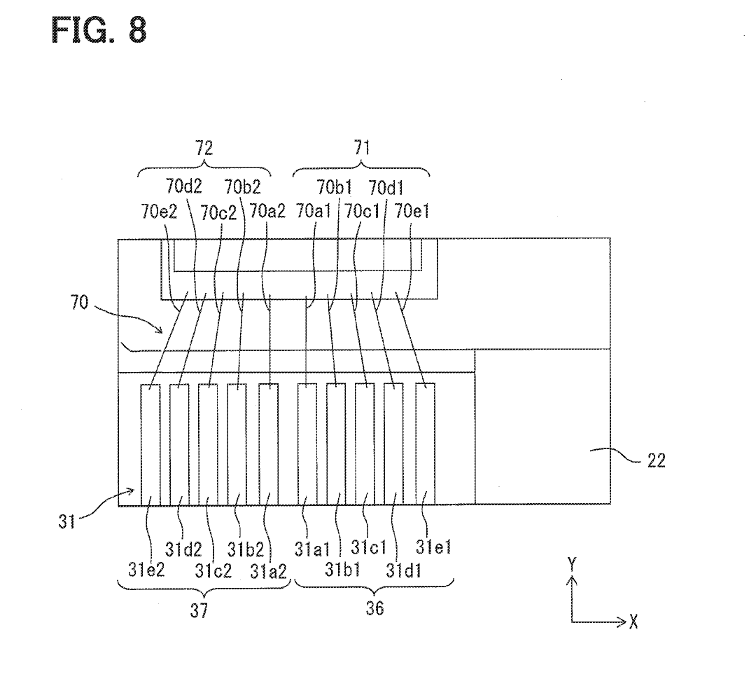

The aforementioned embodiment can also be applied to a configuration not including the driver ICs 40 to 45. A first variation in FIG. 8 corresponds to FIG. 6 and illustrates a lower arm of a U-phase. In the first variation, an analog signal is also transmitted to a control terminal 31 so that a self-inductance is to be considered while including the control terminal 31. As a result, the control terminal 31 is branched off into two parts as well to form a first terminal group 36 and a second terminal group 37. The first terminal group 36 includes control terminals 31a1, 31b1, 31c1, 31d1, and 31e1. The second terminal group 37 includes control terminals 31a2, 31b2, 31c2, 31d2, and 31e2. The control terminals 31a1 and 31a2 are provided for a cathode potential of a temperature-sensitive diode, for example, where the control terminal 31a1 is connected to a bonding wire 70a1 while the control terminal 31a2 is connected to a bonding wire 70a2. The rest of the description will be omitted. The arrangement of a signal path in the X-direction is the same as the arrangement of the bonding wire 70 described above. An output terminal 22 being a main terminal is arranged side by side with each signal path in the X-direction. Accordingly, the configuration illustrated in the first variation allows five signal paths to have nearly equal combined inductances. As a result, when a large current 75 flows instantaneously, a noise voltage generated in each signal path is nearly equal to thus be able to prevent a malfunction of a semiconductor chip 11 or the driver IC 41 resulting from noise. While the lower arm side of the U-phase is described as an example in FIG. 8, another arm can also be configured in a similar manner.

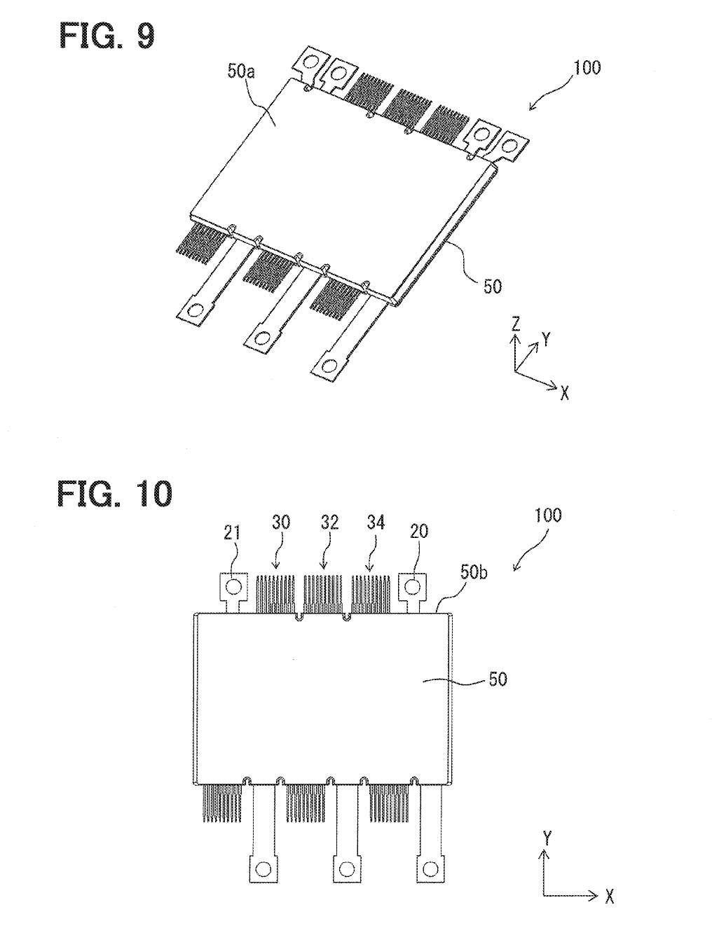

The aforementioned embodiment can also be applied to a configuration in which heat-dissipating surfaces of heat sinks 60 to 67 are not exposed from an encapsulating portion 50, namely a configuration in which an insulating sheet 51 is not stuck to the encapsulating portion, as with a second variation illustrated in FIG. 9. Moreover, the aforementioned embodiment can be applied to a configuration in which the heat-dissipating surfaces of only the heat sinks 60 to 63 are exposed or a configuration in which the heat-dissipating surfaces of only the heat sinks 64 to 67 are exposed.

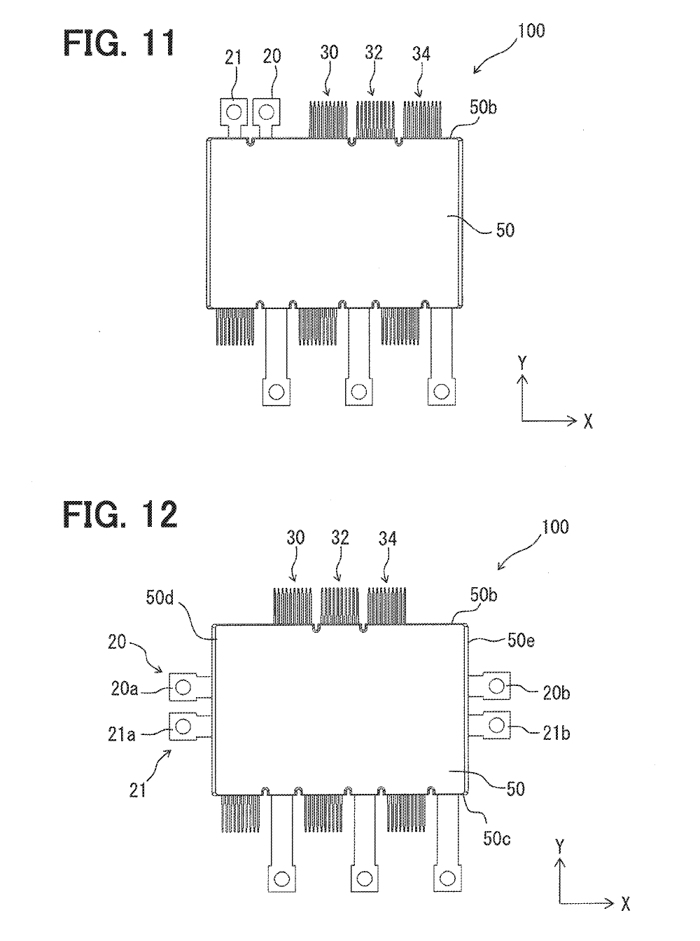

The arrangement of a P-terminal 20 and an N-terminal 21 being the main terminals is not limited to what is illustrated in the aforementioned example. Only one of each of a P-terminal 20 and an N-terminal 21 may be included as with a third variation illustrated in FIG. 10. A P-terminal 20 and an N-terminal 21 may be arranged together on one side of control terminals 30, 32, and 34 in the X-direction as with a fourth variation illustrated in FIG. 11. A P-terminal 20 and an N-terminal 21 may be arranged on side faces 50d and 50e different from side faces 50b and 50c on which control terminals 30 to 35 are provided, as with a fifth variation illustrated in FIG. 12. Each of the P-terminal 20 and the N-terminal 21 is provided as a pair in FIG. 12, where terminals 20a and 21a are arranged on the side face 50d while terminals 20b and 21b are arranged on the side face 50e opposite to the side face 50d.

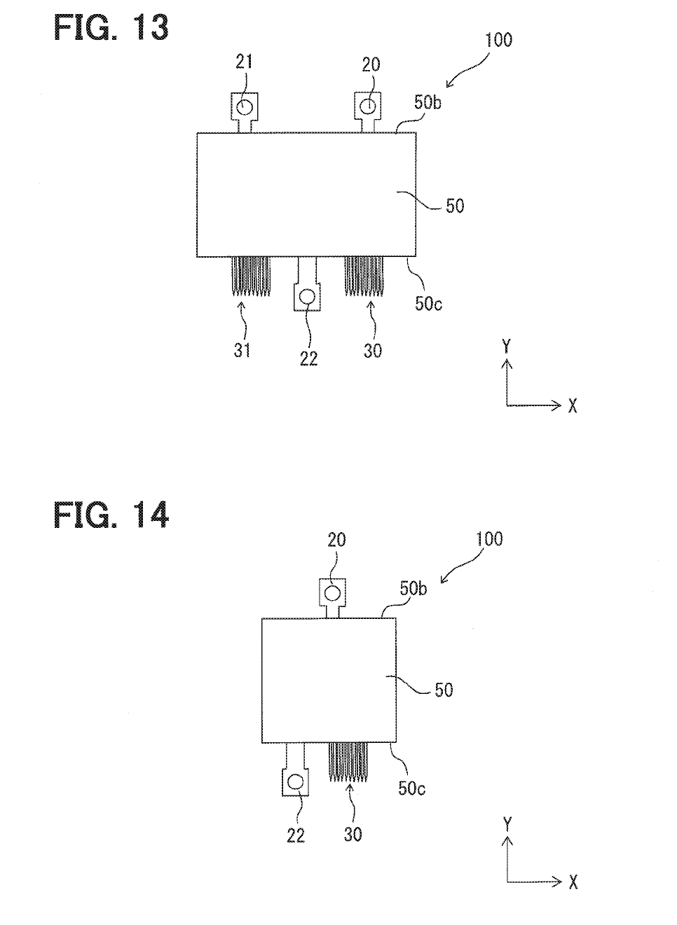

The aforementioned embodiment can also be applied to a semiconductor device 100 not adopting a 6-in-1 package. According to a sixth variation illustrated in FIG. 13, for example, a semiconductor device 100 is a 2-in-1 package including only one phase of upper/lower arms. FIG. 13 illustrates the semiconductor device 100 including the upper/lower arms for a U-phase as an example. A P-terminal 20 and an N-terminal 21 protrude from a side face 50b of an encapsulating portion 50, whereas an output terminal 22 and control terminals 30 and 31 protrude from an opposite side face 50c. The aforementioned structure is then adopted to a signal path including each of the control terminals 30 and 31 provided alongside the output terminal 22. There can also be adopted a configuration in which the control terminals 30 and 31 are provided on the side face 50b.

According to a seventh variation illustrated in FIG. 14, a semiconductor device 100 is a 1-in-1 package including only one arm. FIG. 14 illustrates the semiconductor device 100 including an upper arm for a U-phase as an example. A P-terminal 20 protrudes from a side face 50b of an encapsulating portion 50, whereas an output terminal 22 and a control terminal 30 protrude from an opposite side face 50c. The aforementioned structure is then adopted to a signal path including the control terminal 30 provided alongside the output terminal 22. There can also be adopted a configuration in which the control terminal 30 is provided on the side face 50b.

### Second Embodiment

A description of a part common to that of the semiconductor device 100 illustrated in the first embodiment will be omitted in the present embodiment,

The present embodiment is the same as the first embodiment in terms of the technical idea in which combined inductances of five signal paths are nearly equal, and so is a noise voltage generated in each signal path when a large current 75 flows instantaneously.

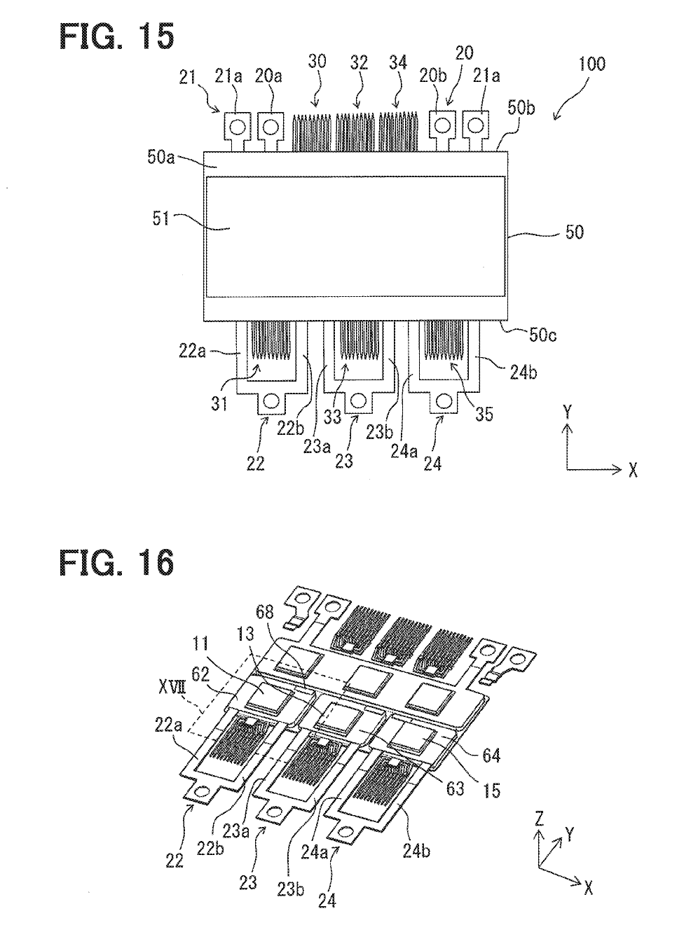

In the present embodiment, each of output terminals 22 to 24 is provided as a pair, as illustrated in FIGS. 15 and 1.6. The output terminal 22 for a U-phase is branched off to have two output terminals 22a and 22b. The two output terminals are arranged on both sides of a signal path of a lower arm for the U-phase while interposing a control terminal 31 for the U-phase, namely the signal path including the control terminal 31, between the output terminals in the X-direction. Likewise, the output terminal 23 for a V-phase is branched off to have two output terminals 23a and 23b. The two output terminals are arranged on both sides of a signal path of a lower arm for the V-phase while interposing a control terminal 33 for the V-phase, namely the signal path including the control terminal 33, between the output terminals in the X-direction. The output terminal 24 for a W-phase is branched off to have two output terminals 24a and 24b. The two output terminals are arranged on both sides of a signal path of a lower arm for the W-phase while interposing a control terminal 35 for the W-phase, namely the signal path including the control terminal 35, between the output terminals in the X-direction. Each of the output terminals 22 to 24 is substantially U-shaped. Note that a P-terminal 20 and an N-terminal 21 are provided in pairs as with the first embodiment,

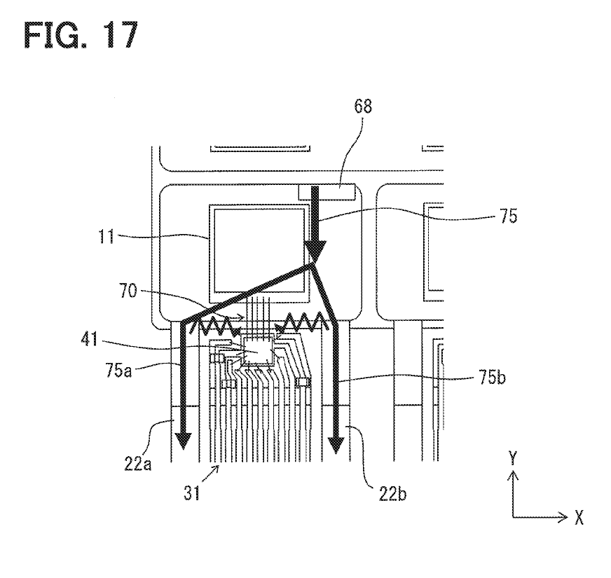

A bonding wire 70 is not provided as a pair as illustrated in the lower arm for the U-phase in FIG. 17, whereby each signal path corresponds to one bonding wire 70. The rest of the configuration is the same as that of the first embodiment.

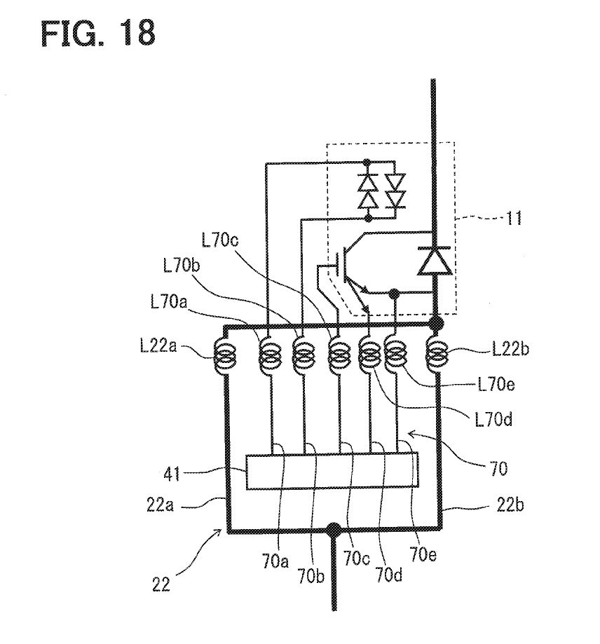

An effect of a semiconductor device 100 according to the present embodiment will now be described with reference to FIGS. 17 and 18. While the effect will be described by taking the lower arm side of the U-phase as an example, the description applies to the other arm as well. FIG. 18 illustrates an equivalent circuit diagram of the configuration illustrated in FIG. 17.

The semiconductor device 100 also includes a driver IC 41 in the present embodiment. Accordingly, as described in the first embodiment, a self-inductance of the bonding wire 70 may be considered in considering a mutual inductance between the signal path and the output terminal 22.

When the output terminal 22 experiences a ground fault causing a large current 75 to flow instantaneously from the P-terminal 20 toward the output terminal 22 via a link portion 68 as illustrated in FIG. 17, for example, the current flows into each of the output terminals 22a and 22b. As a result, a mutual inductance obtained by combining a mutual inductance between a first signal path and the output terminal 22a and a mutual inductance between a first signal terminal and the output terminal 22b is a mutual inductance between the first signal path and the output terminal 22. The same applies to another signal path.

As illustrated in FIG. 18, a bonding wire 70a, a bonding wire 70b, a bonding wire 70c, a bonding wire 70d and a bonding wire 70e are arranged in this order from the output terminal 22a along the X-direction. The bonding wire 70a is provided for a cathode potential of a temperature-sensitive diode formed on a semiconductor chip 11, whereas the bonding wire 70b is provided for an anode potential of the diode. The bonding wire 70c is provided for a gate drive signal of an IGBT device, and the bonding wire 70d is provided for a current sense. The bonding wire 70e is provided for a Kelvin emitter having a reference potential (ground) for each signal path.

FIG. 18 also illustrates a self-inductance L22a of the output terminal 22a and a self-inductance L22b of the output terminal 22b. Also illustrated are self-inductances L70a, L70b, L70c, L70d , and L70e of the bonding wire 70a, the bonding wire 70b, the bonding wire 70c, the bonding wire 70d and the bonding wire 70e , respectively.

The bonding wire 70e is the farthest from the output terminal 22a and the closest to the output terminal 22b, the bonding wire making up a fifth signal path provided for the Kelvin emitter corresponding to the reference potential of each signal path. The mutual inductance is thus small between the bonding wire 70e and the output terminal 22a and large between the bonding wire 70e and the output terminal 22b. Therefore, a combined mutual inductance, namely a mutual inductance of the fifth signal path, takes nearly a median value of the mutual inductances.

Likewise, the bonding wire 70d making up a fourth signal path is the second farthest from the output terminal 22a and the second closest to the output terminal 22b. Therefore, a mutual inductance (combined mutual inductance) of the fourth signal path is nearly equal to the mutual inductance of the fifth signal path.

The bonding wire 70c making up a third signal path is the third farthest from the output terminal 22a and the third closest to the output terminal 22b. Therefore, the mutual inductance (combined mutual inductance) of the third signal path is also nearly equal to the mutual inductance of the fifth signal path.

The bonding wire 70b making up a second signal path is the second closest to the output terminal 22a and the second farthest from the output terminal 22b. Therefore, the mutual inductance (combined mutual inductance) of the second signal path is also nearly equal to the mutual inductance of the fifth signal path.

The bonding wire 70b making up the first signal path is the closest to the output terminal 22a and the farthest from the output terminal 22b. Therefore, the mutual inductance (combined mutual inductance) of the first signal path is also nearly equal to the mutual inductance of the fifth signal path.

The five signal paths have nearly equal combined inductances in the present embodiment, as described above. This allows each signal path to have a nearly equal noise voltage when the large current 75 flows instantaneously. As a result, with the noise being superimposed, there is almost no difference in potential of each signal path with reference to the Kelvin emitter potential, The malfunction of the semiconductor chip 11 or the driver IC 41 resulting from the noise can thus be prevented.

Note that not only the output terminals 22 to 24 but also the P-terminal 20 and the N-terminal 21 are provided in pairs. A signal path including each of control terminals 30, 32, and 34 on an upper arm side is arranged between P-terminals 20a and 20b. The signal path including each of the control terminals 30, 32, and 34 on the upper arm side is also arranged between N-terminals 21a and 21b. Therefore, a malfunction resulting from noise can be prevented in the signal paths of three semiconductor chips 10, 12 and 14 on the upper arm side. The same configuration is adopted in the first embodiment (refer to FIG. 2) so that the same effect can be obtained. That is, the effect of the pair of the bonding wires 70 and the effect of the pair of each of the P-terminals 20 and the N-terminals 21 can be obtained in the signal paths of the three semiconductor chips 10, 12 and 14 on the upper arm side illustrated in the first embodiment.

Moreover, in the present embodiment, the P-terminal 20, the N-terminal 21, and the control terminals 30, 32 and 34 protrude from a side face 50b of an encapsulating portion 50 and extend in a direction orthogonal to the Z-direction, whereas the output terminals 22 to 24 and the control terminals 31, 33 and 35 protrude from an opposite side face 50c and extend in the direction orthogonal to the Z-direction. The build in the Z-direction can be reduced in size as a result. Moreover, heat generated in the semiconductor device 100 can be dissipated through both faces of the device in the Z-direction. Particularly in the present embodiment, heat-dissipating surfaces of heat sinks 60 to 67 are exposed so that heat dissipation can be enhanced while preventing the malfunction resulting from the noise.

(Variation)

In the present embodiment, there has been described the example where all of the P-terminal 20, the N-terminal 21 and the output terminals 22 to 24 being the main terminals are provided in pairs. However, some of the plurality of the main terminals may be provided in pairs instead. Only the output terminals 22 to 24 may be provided in pairs, for example.

Each of the output terminals 22 to 24 is branched off to be substantially U-shaped but may be separated into two as with the P-terminal 20 and the N-terminal 21. On the contrary, the P-terminal 20 and the N-terminal 21 may be branched off as with the output terminals 22 to 24.

The arrangement of the P-terminal 20 and the N-terminal 21 is not limited, as with the first embodiment. Moreover, the aforementioned embodiment can be applied to a configuration in which none of the heat-dissipating surfaces of the heat sinks 60 to 67 is exposed, a configuration in which the heat-dissipating surfaces of only the heat sinks 60 to 63 are exposed or a configuration in which the heat-dissipating surfaces of only the heat sinks 64 to 67 are exposed.

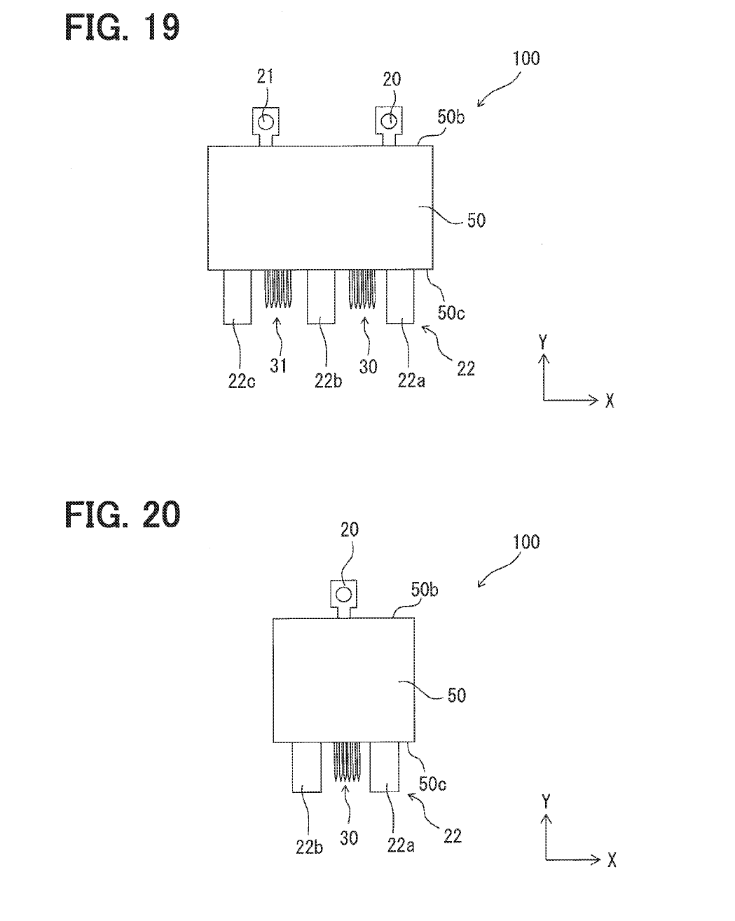

The configuration of the semiconductor device 100 is not limited to a 6-in-1 package, either. That is, the aforementioned embodiment can be applied to a 2-in-1 package or 1-in-1 package. According to an eighth variation illustrated in FIG. 19, for example, a semiconductor device 100 is a 2-in-1 package including only one phase of upper/lower arms. FIG. 19 illustrates the semiconductor device 100 including the upper/lower arms for a U-phase as an example. A P-terminal 20 and an N-terminal 21 protrude from a side face 50b of an encapsulating portion 50, whereas an output terminal 22 and control terminals 30 and 31 protrude from an opposite side face 50c. A pair of output terminals 22a and 22b are arranged on both sides of the control terminal 30, while a pair of output terminals 22b and 22c are arranged on both sides of the control terminal 31 along the X-direction. The output terminal 22b is shared between the control terminals 30 and 31. The semiconductor device can also be configured to include only the output terminals 22a and 22c in the example illustrated in FIG. 19. This however causes an imbalance in the distance between the signal path and the output terminals 22a and 22b. In such a case, the center of the pair of the output terminals 22a and 22b may be adjusted to correspond with the center of the signal path along the X-direction. Moreover, the control terminals 30 and 31 may be arranged between the P-terminal 20 and the N-terminal 21, which are provided in pairs. FIG. 19 illustrates the example where driver ICs 40 and 41 are not provided, and each of the control terminals 30 and 31 includes five terminals. It is needless to say that the semiconductor device may be configured to include the driver ICs 40 and 41.

According to a ninth variation illustrated in FIG. 20, a semiconductor device 100 is a 1-in-1 package including only one arm. FIG. 20 illustrates the semiconductor device 100 including an upper arm for a U-phase as an example. A P-terminal 20 protrudes from a side face 50b of an encapsulating portion 50, whereas an output terminal 22 and a control terminal 30 protrude from an opposite side face 50c. The output terminal 22 includes a pair of output terminals 22a and 22b, between which a signal path including the control terminal 30 is arranged. The semiconductor device may also be configured to include the control terminal 30 on the side face 50b and include a pair of the P-terminals 20. FIG. 20 illustrates the example where a driver IC 40 is not provided, and the control terminal 30 includes five terminals. It is needless to say that the semiconductor device may be configured to include the driver IC 40.

While the preferred embodiments of the present disclosure have been described, the present disclosure is not to be limited to the aforementioned embodiments but can be modified in various manners and implemented without departing from the gist of the present disclosure.

While the bonding wire 70 is illustrated as an example of the relay member, it is not limited such an example. Another member can be adopted as long as the member performs an electrical relay between the semiconductor chips 10 to 15 and the corresponding driver ICs 40 to 45, or between the semiconductor chips 10 to 15 and the corresponding control terminals 30 to 35.

While each of the side faces 50b and 50c is illustrated as an example of the one face of the encapsulating portion 50, the one face is not limited to the side face.

1. A semiconductor device comprising:
at least one semiconductor chip on which a switching device is arranged and that includes a pair of main electrodes and a plurality of control electrodes;
an encapsulating portion that encapsulates the at least one semiconductor chip;
a plurality of main terminals that are electrically connected to the main electrodes and protrude from the encapsulating portion;
a plurality of relay members that are respectively connected to the plurality of control electrodes; and
a plurality of control terminals that are respectively electrically connected to the plurality of control electrodes through the plurality of relay members, generate a plurality of signal paths together with the respective relay members, and protrude from the encapsulating portion, wherein:
the plurality of main terminals include
first main terminals protruding from one face of the encapsulating portion, and
second main terminals protruding from a face different from the one face;
the plurality of control terminals corresponding to a same semiconductor chip protrude from the one face, the plurality of signal paths including the control terminals are arranged side by side in a first direction, and the first main terminals are arranged alongside the plurality of signal paths in the first direction;
the relay members having a same function are provided in a pair at each of the plurality of signal paths arranged side by side with the first main terminals; and
a first relay group including one of the pair of the relay members and a second relay group including another one of the pair are arranged next to each other along the first direction while an order of arrangement of the first relay group and the second relay group exhibits a mirror-inverted relationship.

2. The semiconductor device according to claim 1, wherein:
the plurality of main terminals include
a high potential-side power supply terminal connected to a power supply line on a high potential side,
a low potential-side power supply terminal connected to a power supply line on a low potential side, and
output terminals provided for three phases and for performing an output to a load;
the at least one semiconductor chip includes
upper arm semiconductor chips provided for three phases and connected to the high potential-side power supply terminal, and
lower arm semiconductor chips provided for three phases and connected to the low potential-side power supply terminal;
the output terminals for the respective phases and the control terminals for the respective phases connected to one of the upper arm semiconductor chips and the lower arm semiconductor chips protrude from a same face of the encapsulating portion; and
the output terminals for the respective phases are configured as the first main terminals, and bonding wires for the respective phases are provided in a pair.

3. A semiconductor device comprising:
at least one semiconductor chip on which a switching device is arranged and that includes a pair of main electrodes and a plurality of control electrodes;
an encapsulating portion that encapsulates the semiconductor chip;
a plurality of main terminals that are electrically connected to the main electrodes and protrude from the encapsulating portion;
a plurality of relay members that are respectively connected to the plurality of control electrodes; and
a plurality of control terminals that are electrically connected to the plurality of control electrodes through the plurality of relay members, form a plurality of signal paths together with the respective relay members, and protrude from the encapsulating portion, wherein:
the plurality of main terminals include
first main terminals protruding from one face of the encapsulating portion, and
second main terminals protruding from a face different from the one face;
the plurality of control terminals corresponding to a same semiconductor chip protrude from the one face, the signal paths including the control terminals are arranged side by side in a first direction, and the first main terminals are arranged alongside the signal paths in the first direction;
the first main terminals having a same function are provided in a pair; and
the pair of the first main terminals are arranged at both sides of a plurality of the signal paths while interposing the plurality of the signal paths between the first main terminals in the first direction.

4. The semiconductor device according to claim 3, wherein:
the main terminals include
a high potential-side power supply terminal connected to a power supply line on a high potential side,
a low potential-side power supply terminal connected to a power supply line on a low potential side, and
output terminals provided for three phases and for performing an output to a load;
the at least one semiconductor chip includes
upper arm semiconductor chips provided for three phases and connected to the high potential-side power supply terminal, and
lower arm semiconductor chips provided for three phases and connected to the low potential-side power supply terminal;
the output terminals for the respective phases and the control terminals for the respective phases connected to one of the upper arm semiconductor chips and the lower arm semiconductor chips protrude from the same face of the encapsulating portion; and
the output terminals for the respective phases are configured as the first main terminals provided in a pair and interpose the signal paths for the respective phases between the pair.

5. The semiconductor device according to claim 2, wherein:
the main electrodes are arranged on both faces of the semiconductor chip in a thickness direction;
the output terminals for the respective phases and the control terminals for the respective phases connected to one of the upper arm semiconductor chips and the lower arm semiconductor chips protrude from one side face connecting faces of the encapsulating portion in the thickness direction and extend in a direction orthogonal to the thickness direction; and
the power supply terminals and the control terminals for the respective phases connected to another one of the upper arm semiconductor chips and the lower arm semiconductor chips protrude from a face opposite to the side face and extend in the direction orthogonal to the thickness direction.

6. The semiconductor device according to claim 1,
wherein the plurality of signal paths and the first main terminals are arranged side by side in the first direction such that mutual inductances generated by the respective signal paths and first main terminals are equal in value in all of the signal paths.

7. The semiconductor device according to claim 1, further comprising:
a driver chip on which a circuit controlling drive of the switching device is arranged, wherein:
the relay members electrically relay the driver chip and the control electrodes; and
the control terminals are connected to the relay members through the driver chip.

8. The semiconductor device according to claim 4, wherein:
the main electrodes are arranged on both faces of the semiconductor chip in a thickness direction;
the output terminals for the respective phases and the control terminals for the respective phases connected to one of the upper arm semiconductor chips and the lower arm semiconductor chips protrude from one side face connecting faces of the encapsulating portion in the thickness direction and extend in a direction orthogonal to the thickness direction; and
the power supply terminals and the control terminals for the respective phases connected to another one of the upper arm semiconductor chips and the lower arm semiconductor chips protrude from a face opposite to the side face and extend in the direction orthogonal to the thickness direction.

9. The semiconductor device according to claim 3,
wherein the plurality of signal paths and the first main terminals are arranged side by side in the first direction such that mutual inductances generated by the respective signal paths and first main terminals are equal in value in all of the signal paths.

10. The semiconductor device according to claim 3, further comprising:
a driver chip on which a circuit controlling drive of the switching device is arranged, wherein:
the relay members electrically relay the driver chip and the control electrodes; and
the control terminals are connected to the relay members through the driver chip.
